(19) United States
(12) Patent Application Publication
(10) Pub. No.: US 2023/0385476 A1
(43) Pub. Date: Nov. 30, 2023

(54) AUTOMATED LIVE PROPERTIES COMPONENT UPDATE IN RESERVOIR SIMULATION MODEL

(71) Applicant: Saudi Arabian Oil Company, Dhahran (SA)

(72) Inventors: Belkhir Mokdad, Dhahran (SA); Saad Al Garni, Dhahran (SA); Mouloud Belharche, Dhahran (SA); Fahd Zerrouki, Dhahran (SA)

(21) Appl. No.: 17/804,043

(22) Filed: May 25, 2022

(51) Int. Cl. G06F 30/20; E21B 49/00

(52) U.S. Cl. CPC G06F 30/20; E21B 49/00; E21B 2200/20

(57) ABSTRACT

An automated method for dynamically modelling a petroleum reservoir having a plurality of petroleum wells includes: running an integrated reservoir model of the petroleum reservoir built from measurements of the petroleum reservoir and through history matching on a respective plurality of measurement data from the plurality of petroleum wells, in order to describe an operational behavior of the petroleum reservoir based on a set of parameters calibrated by the plurality of measurement data; obtaining new measurement data from a new petroleum well of the petroleum reservoir; updating the set of calibrated parameters to reflect the new measurement data within a predefined distance of the new petroleum well while not updating the set of calibrated parameters outside the predefined distance of the new petroleum well; and running the integrated reservoir model with the updated set of calibrated parameters in order to reflect the new petroleum well in the integrated reservoir model.

### FIELD OF THE DISCLOSURE

The present disclosure relates in general to petroleum reservoir simulation and in particular to an automated live properties component update in a petroleum reservoir simulation model.

### BACKGROUND OF THE DISCLOSURE

Petroleum is deposited in subsurface formations called reservoirs. It is recovered from the reservoirs by drilling. The drilling reduces the amount of petroleum in the reservoir over time. Petroleum reservoir simulation and modeling is the science of estimating the size and production of a petroleum reservoir over time using a variety of geological and production measurements. The reservoir is a complex geological formation and the type, amount, and distribution of petroleum occupying the reservoir are crucial factors for determining if and how to recover it. Reservoir simulation is a complex process bringing many disciplines together to produce accurate models. However, the evolution of the reservoir over time from the petroleum recovery makes modeling the reservoir a moving target, which can be quite challenging and time-consuming.

It is in regard to these and other problems in the art that the present disclosure is directed to provide a technical solution for an effective petroleum reservoir simulation model using an automated live properties component update workflow.

### SUMMARY OF THE DISCLOSURE

According to a first aspect of the disclosure, an automated method for dynamically modelling a petroleum reservoir is provided. The method comprises running, by a processing circuit, an integrated reservoir model of the petroleum reservoir built from an integrated database of data obtained from measurements of the petroleum reservoir and stored on a non-transitory storage device. The integrated database of data comprises static data that does not change over time, and dynamic data that changes over time. The petroleum reservoir has a plurality of petroleum wells represented in the integrated reservoir model. The integrated database comprises an integration of data obtained from different reservoir disciplines. The integrated reservoir model is built from the different reservoir disciplines and comprises an integration of a static model built from the static data, and a dynamic model built from the dynamic data. The integrated reservoir model is further built through history matching on a respective plurality of measurement data from the plurality of petroleum wells and that is stored in the integrated database, in order to describe an operational behavior of the petroleum reservoir in terms of a set of parameters calibrated by the plurality of measurement data. The method further comprises: obtaining, by the processing circuit, new measurement data from a new petroleum well of the petroleum reservoir and that is not part of the plurality of petroleum wells; storing, by the processing circuit, the obtained new measurement data in the integrated database; updating, by the processing circuit, the set of calibrated parameters to reflect the stored new measurement data within a predefined distance of the new petroleum well while not updating the set of calibrated parameters outside the predefined distance of the new petroleum well; and running, by the processing circuit, the integrated reservoir model with the updated set of calibrated parameters in order to reflect the new petroleum well in the integrated reservoir model.

In an embodiment consistent with the above, the different reservoir disciplines comprise three or more of geology, geophysics, petrophysics, reservoir engineering, and fluid dynamics.

In an embodiment consistent with the above, the measurement data for each petroleum well of the petroleum reservoir comprises a well top, a deviation survey, a porosity log, a permeability log, and an initial water saturation.

In an embodiment consistent with the above, the static model incorporates structural, stratigraphical, and petrophysical features of the petroleum reservoir.

In an embodiment consistent with the above, the static model comprises spatial position information of different formations, faults, folds, and the plurality of petroleum wells in the petroleum reservoir.

In an embodiment consistent with the above, the measurement data comprises pressure-volume-temperature (PVT) data, special core analysis (SCAL) data, oil production data, pressure data, and vertical lift performance (VLP) data.

In an embodiment consistent with the above, the method further comprises running the integrated reservoir model with the updated set of calibrated parameters in order to identify areas of unswept oil.

According to another aspect of the disclosure, an automated system for dynamically modelling a petroleum reservoir is provided. The system comprises: a processing circuit; a first non-transitory storage device storing an integrated reservoir model of the petroleum reservoir built from an integrated database of data obtained from measurements of the petroleum reservoir; a second non-transitory storage device storing the integrated database of data; and a third non-transitory storage device storing instructions thereon that, when executed by the processing circuit, cause the processing circuit to run the integrated reservoir model. The integrated database of data comprises static data that does not change over time, and dynamic data that changes over time. The petroleum reservoir has a plurality of petroleum wells represented in the integrated reservoir model. The integrated database comprises an integration of data obtained from different reservoir disciplines. The integrated reservoir model is built from the different reservoir disciplines and comprises an integration of a static model built from the static data, and a dynamic model built from the dynamic data. The integrated reservoir model is further built through history matching on a respective plurality of measurement data from the plurality of petroleum wells and that is stored in the integrated database, in order to describe an operational behavior of the petroleum reservoir in terms of a set of parameters calibrated by the plurality of measurement data. The instructions, when executed by the processing circuit, further cause the processing circuit to: obtain new measurement data from a new petroleum well of the petroleum reservoir and that is not part of the plurality of petroleum wells; store the obtained new measurement data in the integrated database; update the set of calibrated parameters to reflect the stored new measurement data within a predefined distance of the new petroleum well while not updating the set of calibrated parameters outside the predefined distance of the new petroleum well; and run the integrated reservoir model with the updated set of calibrated parameters in order to reflect the new petroleum well in the integrated reservoir model.

In an embodiment consistent with the system described above, the different reservoir disciplines comprise three or more of geology, geophysics, petrophysics, reservoir engineering, and fluid dynamics.

In an embodiment consistent with the system described above, the measurement data for each petroleum well of the petroleum reservoir comprises a well top, a deviation survey, a porosity log, a permeability log, and an initial water saturation.

In an embodiment consistent with the system described above, the static model incorporates structural, stratigraphical, and petrophysical features of the petroleum reservoir.

In an embodiment consistent with the system described above, the static model comprises spatial position information of different formations, faults, folds, and the plurality of petroleum wells in the petroleum reservoir.

In an embodiment consistent with the system described above, the measurement data comprises pressure-volume-temperature (PVT) data, special core analysis (SCAL) data, oil production data, pressure data, and vertical lift performance (VLP) data.

In an embodiment consistent with the system described above, the instructions, when executed by the processing circuit, further cause the processing circuit to run the integrated reservoir model with the updated set of calibrated parameters in order to identify areas of unswept oil.

According to yet another aspect of the disclosure, a non-transitory computer readable medium (CRM) is provided. The CRM has computer instructions stored therein that, when executed by a processing circuit, cause the processing circuit to carry out an automated process of dynamically modelling a petroleum reservoir. The process comprises running an integrated reservoir model of the petroleum reservoir built from an integrated database of data obtained from measurements of the petroleum reservoir and stored on a non-transitory storage device. The integrated database of data comprises static data that does not change over time, and dynamic data that changes over time. The petroleum reservoir has a plurality of petroleum wells represented in the integrated reservoir model. The integrated database comprises an integration of data obtained from different reservoir disciplines. The integrated reservoir model is built from the different reservoir disciplines and comprises an integration of a static model built from the static data, and a dynamic model built from the dynamic data. The integrated reservoir model is further built through history matching on a respective plurality of measurement data from the plurality of petroleum wells and that is stored in the integrated database, in order to describe an operational behavior of the petroleum reservoir in terms of a set of parameters calibrated by the plurality of measurement data. The process further comprises: obtaining new measurement data from a new petroleum well of the petroleum reservoir and that is not part of the plurality of petroleum wells; storing the obtained new measurement data in the integrated database; updating the set of calibrated parameters to reflect the stored new measurement data within a predefined distance of the new petroleum well while not updating the set of calibrated parameters outside the predefined distance of the new petroleum well; and running the integrated reservoir model with the updated set of calibrated parameters in order to reflect the new petroleum well in the integrated reservoir model.

In an embodiment consistent with the CRM described above, the different reservoir disciplines comprise three or more of geology, geophysics, petrophysics, reservoir engineering, and fluid dynamics.

In an embodiment consistent with the CRM described above, the measurement data for each petroleum well of the petroleum reservoir comprises a well top, a deviation survey, a porosity log, a permeability log, and an initial water saturation.

In an embodiment consistent with the CRM described above, the static model incorporates structural, stratigraphical, and petrophysical features of the petroleum reservoir, and the static model comprises spatial position information of different formations, faults, folds, and the plurality of petroleum wells in the petroleum reservoir.

In an embodiment consistent with the CRM described above, the measurement data comprises pressure-volume-temperature (PVT) data, special core analysis (SCAL) data, oil production data, pressure data, and vertical lift performance (VLP) data.

In an embodiment consistent with the CRM described above, the process further comprises running the integrated reservoir model with the updated set of calibrated parameters in order to identify areas of unswept oil.

Any combinations of the various embodiments and implementations disclosed herein can be used. These and other aspects and features can be appreciated from the following description of certain embodiments together with the accompanying drawings and claims.

### BRIEF DESCRIPTION OF THE DRAWINGS

FIG. 1 is a block diagram of an example workflow for dynamically modelling a petroleum reservoir, according to an embodiment.

FIG. 2 is a block diagram of an example workflow for dynamically modelling a petroleum reservoir, according to another embodiment.

FIG. 3 is a block diagram of an example workflow for dynamically modelling a petroleum reservoir, according to yet another embodiment.

FIG. 4 is a flow diagram of an example automated method for dynamically modelling a petroleum reservoir, according to an embodiment.

It is noted that the drawings are illustrative and not necessarily to scale, and that the same or similar features have the same or similar reference numerals throughout.

### DETAILED DESCRIPTION OF CERTAIN EMBODIMENTS OF THE DISCLOSURE

Example embodiments of the present disclosure are directed to techniques for running a petroleum reservoir simulation model using an automated live properties component update workflow. Professionals from multiple reservoir disciplines (e.g., geology, geophysics, petrophysics, and reservoir engineering, to name a few) work together in coordinated shared working environments in order to compile integrated databases, develop interoperable applications, and share earth models. This collaboration results in integrated reservoir models of petroleum reservoirs that allow highly accurate performance modeling of the production of the reservoirs.

However, such reservoir models are complex and relatively static (e.g., unable to incorporate new wells without rebuilding the reservoir model). Accordingly, their modelling accuracy degrades over time until the benefits of a more accurate model outweigh the significant development costs needed to produce a newer, more accurate model.

It is in regard to these and other problems that example embodiments of the present disclosure are directed to automated techniques for dynamically modelling a petroleum reservoir. In one such embodiment, an automated method for dynamically modelling a petroleum reservoir is provided. The method is carried out by a processing circuit (such as a microprocessor or custom logic circuit). The method includes running an integrated reservoir model of the petroleum reservoir. The integrated reservoir model is built from an integrated database of data obtained from measurements of the petroleum reservoir. The integrated database is stored on a non-transitory storage device (such as a disk drive or flash drive). Here, the integrated database of data includes static data (that does not change over time, such as geological data), and dynamic data (that changes over time, such as production data). In addition, the petroleum reservoir has numerous petroleum wells represented in the integrated reservoir model. Further, the integrated database is an integration of data obtained from different reservoir disciplines.

Continuing, the integrated reservoir model is built from the different reservoir disciplines and includes an integration of a static model and a dynamic model. The static model is built from the static data (e.g., logs, structural picks, to name a few). The dynamic model (or the reservoir simulation model) is built through history matching on respective measurement data from the petroleum wells. This dynamic data is stored in the integrated database. As built by the integrated reservoir disciplines, the dynamic model (or the reservoir simulation model) describes an operational behavior of the petroleum reservoir in terms of a set of parameters calibrated by the measurement data.

In addition, the method includes obtaining new measurement data from a new petroleum well (e.g., a different well of the same petroleum reservoir). Here, the new petroleum well is not part of the petroleum wells already modeled in the integrated reservoir model. The method further includes storing the obtained new measurement data in the integrated database. The method also includes updating a properties component of the static model within a defined radius around the new petroleum well without changing any of the calibrated parameters outside of the defined radius. For instance, in one such embodiment, the set of calibrated parameters is updated to reflect the stored new measurement data within a predefined distance of the new petroleum well. On the other hand, the set of calibrated parameters is not updated outside the predefined distance of the new petroleum well. Finally, the method includes running the integrated reservoir model with the updated set of calibrated parameters in order to reflect the new petroleum well in the integrated reservoir model.

In further detail, in an example embodiment, data from various petroleum industry disciplines is integrated (such as during major reservoir studies) in order to produce a model that is representative of the reservoir being studied. The reservoir simulation model is used (e.g., economically and quantitatively) to determine the most viable growth strategy of the field. The model is an integration of different disciplines such as geophysics, geology, and fluid dynamics. The integration process produces and calibrates a reservoir simulation model incorporating all these disciplines.

However, this integration process can take over a year to produce a calibrated reservoir simulation model. From a practical standpoint this model remains valid for only three to five years, at which point the integrated process normally needs to be repeated (and at great cost, given all the professionals and disciplines involved). During the gaps between major simulation model updates, important information can go missing due to newer geological features that are not incorporated in the reservoir simulation model. These omissions can in turn lead to missing opportunities to the company if they are not integrated in the model as soon as a new well is drilled. According to some embodiments, in order to overcome this challenge, a dynamic simulation model augments the static integrated reservoir simulation model, and incorporates new well measurements into the reservoir simulation.

According to some such embodiments, a complete reservoir simulation model integrates a static model and a dynamic model. In some such embodiments, a properties component within the static model incorporates new well information as soon as it is made available throughout the database. According to one embodiment, a method of reservoir simulation is provided. The method includes using a dynamic model (or reservoir simulation model) built through a history matching process of measurement data of the reservoir being simulated.

In one embodiment, the static model is updated immediately after a new well is drilled and measured. For instance, any new information related to the new well (such as well top, deviation survey, porosity log, permeability log, and initial water saturation) is incorporated into the dynamic model without the need of going through a new lengthy integrated reservoir study and a rebuilding of the static model.

In some embodiments, the static model is part in the reservoir modelling process, and incorporates the significant structural, stratigraphical, and petrophysical features of the reservoir. The spatial positions of the different formations, faults, folds, wells, and any information significant enough to have an impact on the characterization are compiled. In some such embodiments, the major stratigraphic features are refined into multi-layers that are related to the bounding surface. In some such embodiments, once the static model is built by the geoscientists, the engineers integrate dynamic data, such as pressure-volume-temperature (PVT), special core analysis (SCAL), production, pressure, and vertical lift performance relationship (VLP), to name a few, with the static model.

In some embodiments, the static model is updated immediately and seamlessly after the well is drilled. Any new information related to the new well (such as well top, deviation survey, porosity log, permeability log, and initial water saturation) is incorporated into the simulation without the need of going throughout a new lengthy integrated reservoir study (IRS). In some such embodiments, dynamic data is integrated with the static model in order to keep the static model alive when new production data (such as from a new well) becomes available. This obviates the need to build a new static model or run a new IRS. In some such embodiments, an automated workflow introduces new measurement information as soon as the data is made available. The workflow is configured (such as programmed) to identify areas of unswept oil from the new measurements. This empowers reservoir engineers to plan better management practices to maximize oil recovery and, as a result, increase company revenues. This also results in more frequent updates to the integrated reservoir model, which increases awareness of important opportunities and critical information. This can lead to better decisions regarding reservoir management.

According to an embodiment, an unexplored workflow approach keeps the static simulation live, while minimizing manual modification and editing post integrated reservoir studies. More specifically, the workflow integrates a new set of data from a new well locally (e.g., within a vicinity of the new well) and without altering the surrounding history-matched calibrated parameters.

In some embodiments, the integrated reservoir studies parameters used by the different stakeholders (e.g., geomodellers, petrophysicists, to name a few) are captured, then stored within the modelling packages project. At this point, these processes are updated with newly drilled well information and without altering the history matched model parameters that are part of the static model. In one such embodiment, contradictory information is noted between real data and the dynamic matched model data (such as for follow-up investigation or dynamic model modification).

The static model component uses techniques for history matching, which introduces uncertainties and limits the practical lifespan of such models to about three to five years. According to some embodiments, the dynamic model removes these uncertainties by incorporating measurements from new wells, with the updated dynamic model being integrated with the static model (history-matched parameters) as part of the integrated reservoir model. This allows measurements from even new wells (such as within the first months after building the static model) to be incorporated in the integrated reservoir model. In some embodiments, this new measurement data is introduced to the dynamic model (and the corresponding uncertainties removed) in real time as the new data becomes available. This eliminates the uncertainties present in static reservoir models.

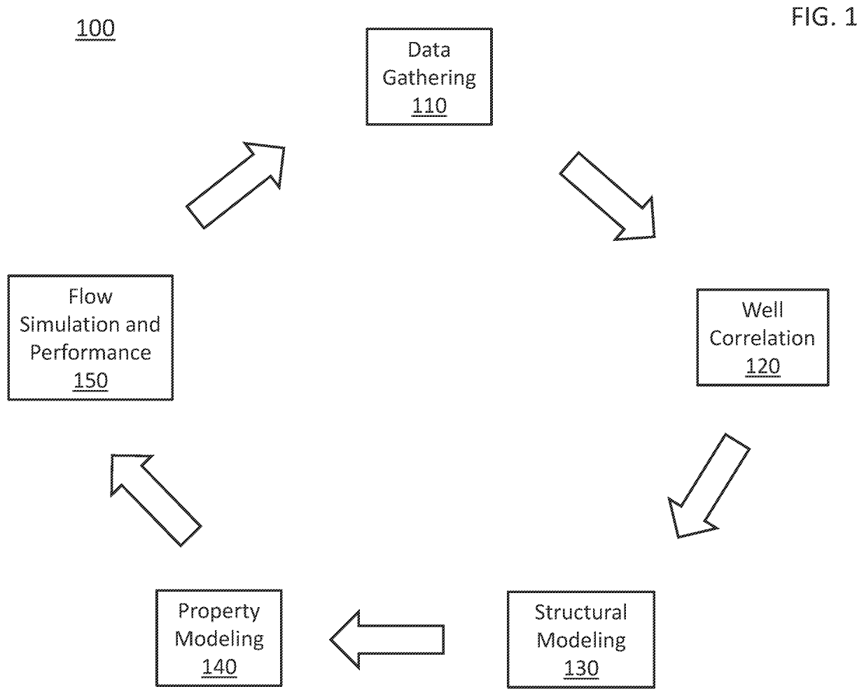

FIG. 1 is a block diagram of an example workflow 100 for dynamically modelling a petroleum reservoir, according to an embodiment. FIG. 1 illustrates the workflow stages for an example live reservoir modelling, according to an embodiment. Put another way, FIG. 1 illustrates the different steps of an example workflow that performs an automated reservoir simulation model update.

With reference to FIG. 1, each workflow cycle starts with data gathering 110, where all new well data (e.g., trajectories, logs, well tops, rock type modelling, Archie parameters, to name a few) are listed and identified as soon as they are quality controlled (QC'ed, such as approved or meeting some objective criteria) and made available for use in modelling. The workflow 100 further includes the step of updating 120 the reservoir framework by correlating the new well measurements, such as the new well tops, which form the foundation of the properties component of the dynamic model. The well tops are initially used to reflect any change in the structure, and so form the basis of the next step, structural modelling 130. At this point, the results of petrophysical interpretations based on indirect measurements of physical responses of rocks and fluids are used for the step of property modelling 140.

Continuing with the workflow 100 of FIG. 1, it is assumed that the same characterizations and equations used during the static modelling are kept for facies modelling or rock typing, which forms the foundation of the final step, flow simulation and performance 150. First, the facies are populated along the wells, and are then propagated to the reservoir simulation model. These facies or rock types are used to help define the fluid saturation through the pre-established equations defined earlier. New properties, such as porosity, permeability, and water saturation, are then generated and re-exported to the simulator to account for the new changes within a certain radius of the new wells. The final output assesses the flow simulation for the new imported wells as well as the reservoir performance. In one embodiment, this flow simulation and performance 150 data is used to design new field development wells while minimizing uncertainties by updating the properties component of the dynamic model as discussed in the workflow 100.

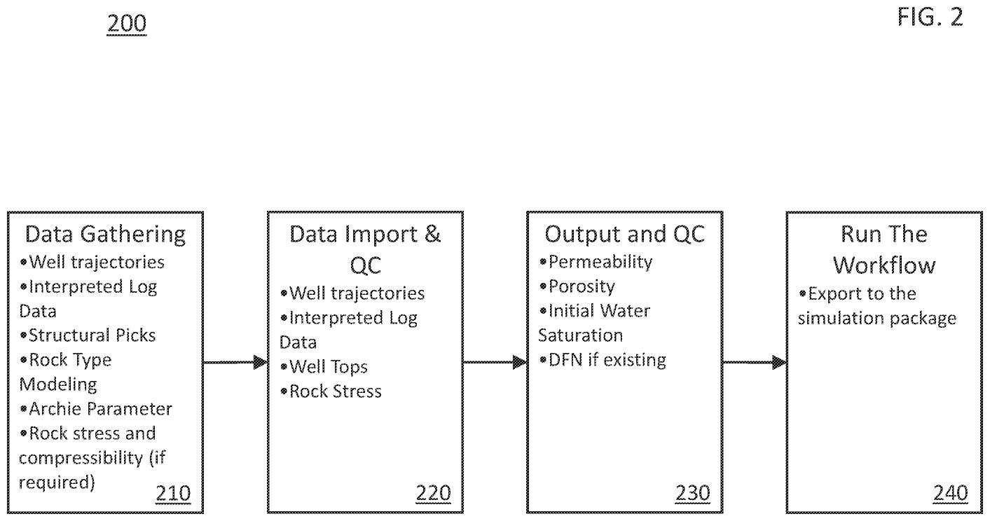

FIG. 2 is a block diagram of an example workflow 200 for dynamically modelling a petroleum reservoir, according to another embodiment. The workflow 200 is similar to the workflow 100, only organized in a different format, including more explicit descriptions of the separate steps. One of the first steps to conducting the workflow 200 is gathering 210 all existing reservoir projects into a software modelling package as well as all existing workflows documented and saved within the software. Depending on the reservoir simulation project, and the approach taken by the multi-disciplinary team, this involves capturing different property modelling processes such as data analysis, facies modelling or rock typing, petrophysical modelling, structural and well tops, production data, well trajectories, interpreted log data, structural picks, rock type modeling, Archie parameters, and rock stress and compressibility (if required), to name a few. The data gathering 210 should be as comprehensive as possible or practical, as any missing information hinders the workflow 200 and delays its successful implementation.

The accuracy of the dynamic model can be additionally checked when adding 220 the measurements (e.g., well trajectories, interpreted log data, well tops, and rock stress, to name a few) from the new wells and performing a blind test. An inconsistent well tie will result in misalignment between the predicted/simulated log and the actual log at the well location. On the other hand, a close match between the predicted/simulated log and the actual log at two well locations will confirm lateral consistency in the well ties. Property and well top data can be used again for historical or comparison purposes, and possible modelling improvements.

The workflow 200 further includes outputting 230 modeled flow simulation and performance data, such as permeability, porosity, initial water saturation, and discrete fracture network (DFN, if existing). The last step is running 240 the workflow, exporting the results to the simulation package.

In an embodiment, measurement data from a newly incorporated well is used with the adopted workflow for porosity and permeability modelling and distribution around the new well. In an embodiment, petrophysical data (such as porosity, permeability, and water saturation) is used to update the structural framework. The measurement data for new wells is inserted into the workflow, and a radius is defined. This radius defines the extent of changes to be implemented in the dynamic model. In the workflow, the input data is read first. After that, a local model update (part of the dynamic model) is performed to account for any changes in structure since the static model was built. After that change, a series of commands (e.g., programmed commands) are executed (e.g., by a processing circuit, such as a microprocessor or computer) to perform the property modelling.

In some embodiments, the current workflow allows direct access to the company database, which enables (through programmed software) identifying and importing new information available through selected filters defined by the user. In one such embodiment, after selecting and importing the new available data, the data is checked against quality control (QC) criteria to determine if the data is valid or anomalous.

In some embodiments, the modelling package is further improved by using an interface, such as a graphical user interface (GUI), to question the end user on several parameters. This includes defining the radius of change, dropping the updated new wells tops, the logs, and 3D static properties to be used in the workflow.

According to an embodiment, once the radius of change is defined, and all input data is incorporated, the automated workflow is configured (e.g., programmed) to sequentially update the different processes. The first step automates the structural gridding based on the new well tops, followed by the petrophysical modelling, which includes upscaling the petrophysical logs.

In some embodiments, all these changes are operated in the dynamic model within a flexible radius of influence from the new well, and will not alter any history matched region in the static model outside the radius of change. In some such embodiments, the model conformance and the evaluation of its update within the region of interest are evaluated, and further insight drawn for model improvement.

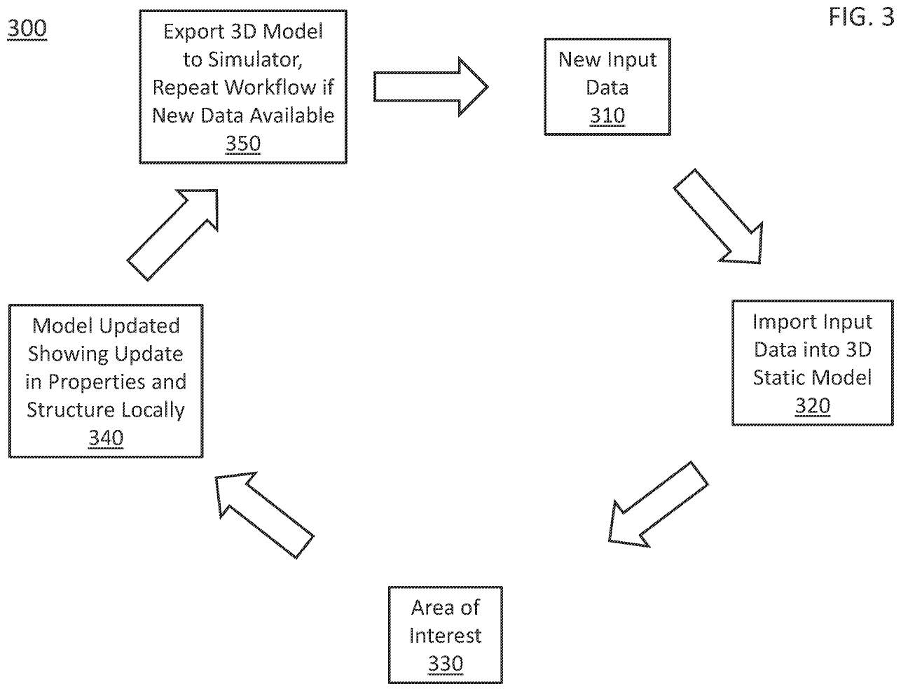

FIG. 3 is a block diagram of an example workflow 300 for dynamically modelling a petroleum reservoir, according to yet another embodiment. FIG. 3 illustrates the life cycle of this workflow 300 from loading 310 the input data to exporting 350 to the simulation engine. The workflow 300 is run in cycles, with each cycle being kicked off by the obtaining 310 of a new set of measurement data (e.g., when there is a new set of measurement data). This new data is then imported 320 into the 3D static model. Here, the static model (history matched model) is not changed, rather an area of interest 330 (such as specified by a radius of influence) is defined. Only the static model is run for desired locations outside the area of interest 330 of any new wells (as represented in the new input data 310), while the dynamic model is run for desired locations within the area of interest 330. The workflow 300 further includes updating 340 the dynamic model to reflect the updated properties and structure locally (e.g., within the radius of influence of the new well). Finally, the workflow 300 includes exporting 350 the 3D model (dynamic model) to the simulator (e.g., integrated reservoir model) and repeating the workflow 300 if new measurement data (such as from a new well) becomes available.

According to some embodiments, by integrating the static and dynamic models, uncertainties inherent in static (history matched) models are removed by the integration of the dynamic model to reflect new well measurement data. As such, no further history matching is needed (e.g., the static model does not change), and all new measurement data is integrated (via the dynamic model) into the integrated model in real time. As such, the integrated model behaves like a live model that is always fully calibrated.

To recap, integrated reservoir studies (IRS) are static history-matched models that are complex and time-consuming to build, and require resources from many different departments. Accordingly, such static models are not practical to build more frequently than every three to five years. After a history matched model is completed, new information acquired by drilling a new well cannot be incorporated in the static model without constructing a new IRS (and investing all the time and resources to do so). To address this situation, according to some embodiments, a dynamic model is integrated with the static (history matched) model. The dynamic model incorporates the new information, such as new well top or water saturation updates, in order to reflect the new well in the integrated model. Without the dynamic model component, such important new information could not be assessed within the reservoir management team, and lead to consequential loss if not assimilated within the team.

According to some embodiments, a workflow is provided for reservoir simulation that: maximizes resource efficiency; enhances the decision-making process; saves time and cost (e.g., no need to perform a field-wide history matching model each time new data becomes available); integrates the latest available drilling well data; allows quick simulation model update of the BI-60 activities without losing the existing history matched (static) model; automates log upscaling and properties modeling using existing model variogram parameters, rock type, and facies modelling; and reduces the uncertainty of the model.

According to some embodiments, the above-described workflow features help to: keep reservoir models live and up-to-date at all times; incorporate all the latest reservoir data, without the need to perform a field-wide history match each time, and preserve existing calibrated models; rely on unique advanced processes that produce geologically robust models and use existing variograms; benefit from a seamless workflow where local updates work across the structural model, grid, and property models; provide flexibility in applying radius of influence in petrophysical modelling, and provide independent radius of influence based on properties.

In further detail, with respect to some embodiments, the developed workflow gathers all relevant input data, such as porosity, permeability and water saturation logs prior to starting the process. All the empirical equations required to generate the different static properties are stored within the workflow, and are readily available to be implemented. Without the workflow, differences between new measurement data and predicted data from a static (history matched) model, if not incorporated in time, can change the geological understanding, and lead to poor investment and bad decisions within the reservoir management. Crucial expertise provided by the simulation engineer can also be improved using this workflow. The workflow allows the integration of all well tops. When the new well is imported into the dynamic model, future well placement is improved. In some embodiments, the dynamic model is updated with this information, as it provides relevant information about missing targets. In some embodiments, the dynamic model is updated with 3D structure information such as the new well tops, and altering the field properties within a limited radius (such as a specified radius). The dynamic model is built without altering the static model.

According to some embodiments, the properties component within a dynamic model is kept live as soon as new well information is made available throughout the database. The static model is preserved where no new well data is present, such as by only running the dynamic model on locations within a specified distance (or radius) surrounding the new wells.

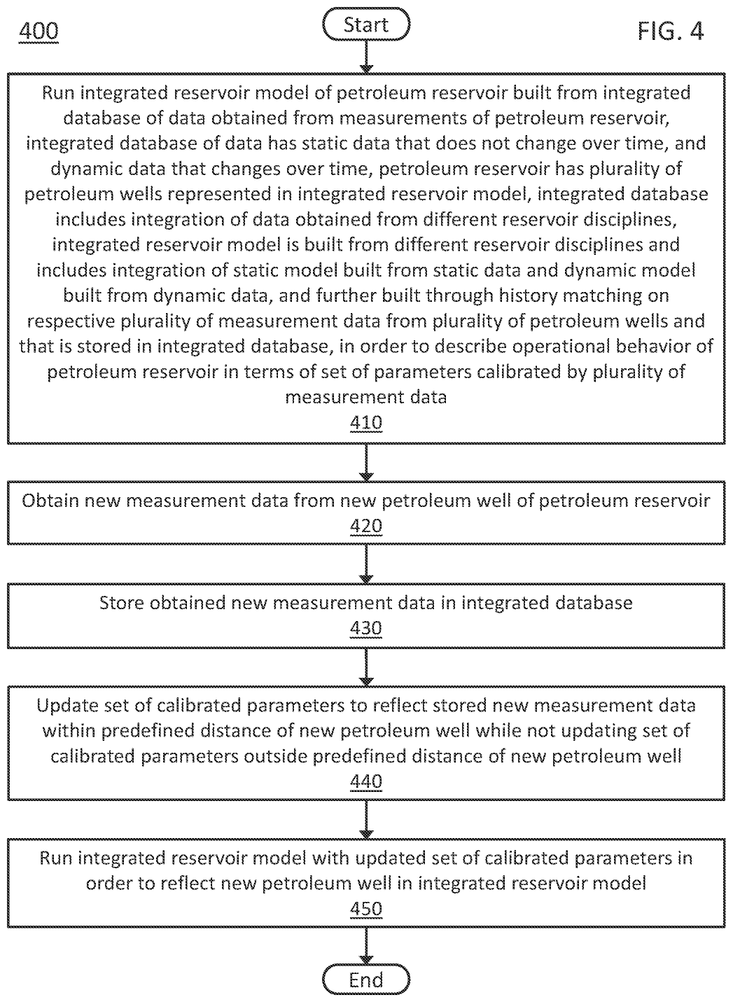

FIG. 4 is a flow diagram of an example automated method 400 for dynamically modelling a petroleum reservoir, according to an embodiment. The method 400 is automated under the control of an electronic circuit (such as a microprocessor), which is configured (e.g., by code, such as programmed, by custom logic, as in configurable logic gates, or the like) to carry out the steps of the method 400.

Some or all of the method 400 can be performed using components and techniques illustrated in FIGS. 1-3. In addition, portions of this and other methods or processes disclosed herein can be performed on or using simulation logic, such as custom or preprogrammed control logic devices, circuits, or processors, as in a programmable logic circuit (PLC), computer, software, or other circuit (e.g., ASIC, FPGA) configured by code or logic to carry out their assigned task. The devices, circuits, or processors can also be, for example, dedicated or shared hardware devices (such as laptops, single board computers (SBCs), workstations, tablets, smartphones, part of a server, or dedicated hardware circuits, as in FPGAs or ASICs, or the like), or computer servers, or a portion of a server or computer system. The devices, circuits, or processors can include a non-transitory computer readable medium (CRM, such as read-only memory (ROM), flash drive, or disk drive) storing instructions that, when executed on one or more processors, cause portions of the method 400 (or other disclosed method or process) to be carried out. It should be noted that in other embodiments, the order of the operations can be varied, and that some of the operations can be omitted. Some of the method 400 can also be performed using logic, circuits, or processors located on or in electrical communication with a processing circuit configured by code to carry out these portions of the method 400.

In the method 400 processing begins with the step of running 410 an integrated reservoir model of the petroleum reservoir. The integrated reservoir model is built from an integrated database of data obtained from measurements of the petroleum reservoir. The integrated database of data is stored on a non-transitory storage device (such as a disk drive, solid state memory, or a flash drive). The integrated database of data includes static data that does not change over time (e.g., porosity and permeability logs, structural picks, and the like) and dynamic data that changes over time (such as production measurements). The petroleum reservoir has a plurality of petroleum wells represented in the integrated reservoir model. The integrated database includes an integration of data obtained from different reservoir disciplines (such as geology, geophysics, petrophysics, reservoir engineering, and fluid dynamics, to name a few). The integrated reservoir model is built from the different reservoir disciplines and includes an integration of a static model built from the static data and a dynamic model built from the dynamic data. The integrated reservoir model is further built through history matching on a respective plurality of measurement data from the plurality of petroleum wells and that is stored in the integrated database, in order to describe an operational behavior of the petroleum reservoir in terms of a set of parameters calibrated by the plurality of measurement data.

The method 400 further includes the step of obtaining 420 new measurement data from a new petroleum well of the petroleum reservoir and that is not part of the plurality of petroleum wells. In addition, the method 400 includes the step of storing 430 the obtained new measurement data in the integrated database. Further, the method 400 includes the step of updating 440 the set of calibrated parameters to reflect the stored new measurement data within a predefined distance of the new petroleum well while not updating the set of calibrated parameters outside the predefined distance of the new petroleum well. The method 400 also includes the step of running 450 the integrated reservoir model with the updated set of calibrated parameters in order to reflect the new petroleum well in the integrated reservoir model.

In an embodiment, the different reservoir disciplines includes three or more of geology, geophysics, petrophysics, reservoir engineering, and fluid dynamics. In an embodiment, the measurement data for each petroleum well of the petroleum reservoir includes a well top, a deviation survey, a porosity log, a permeability log, and an initial water saturation. In an embodiment, the static model incorporates structural, stratigraphical, and petrophysical features of the petroleum reservoir. In an embodiment, the static model includes spatial position information of different formations, faults, folds, and the plurality of petroleum wells in the petroleum reservoir. In an embodiment, the measurement data includes pressure-volume-temperature (PVT) data, special core analysis (SCAL) data, oil production data, pressure data, and vertical lift performance (VLP) data. In an embodiment, the method 400 further includes the step of running the integrated reservoir model with the updated set of calibrated parameters in order to identify areas of unswept oil.

Any of the methods described herein may, in corresponding embodiments, be reduced to a non-transitory computer readable medium (CRM) having computer instructions stored therein that, when executed by a processing circuit, cause the processing circuit to carry out an automated process for performing the respective methods.

The methods described herein may be performed in whole or in part by software or firmware in machine readable form on a tangible (e.g., non-transitory) storage medium. For example, the software or firmware may be in the form of a computer program including computer program code adapted to perform some of the steps of any of the methods described herein when the program is run on a computer or suitable hardware device (e.g., FPGA), and where the computer program may be embodied on a computer readable medium. Examples of tangible storage media include computer storage devices having computer-readable media such as disks, thumb drives, flash memory, and the like, and do not include propagated signals. Propagated signals may be present in a tangible storage media, but propagated signals by themselves are not examples of tangible storage media. The software can be suitable for execution on a parallel processor or a serial processor such that the method steps may be carried out in any suitable order, or simultaneously.

It is to be further understood that like or similar numerals in the drawings represent like or similar elements through the several figures, and that not all components or steps described and illustrated with reference to the figures are required for all embodiments or arrangements.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It is further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Terms of orientation are used herein merely for purposes of convention and referencing and are not to be construed as limiting. However, it is recognized these terms could be used with reference to a viewer. Accordingly, no limitations are implied or to be inferred. In addition, the use of ordinal numbers (e.g., first, second, third) is for distinction and not counting. For example, the use of “third” does not imply there is a corresponding “first” or “second.” Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

The subject matter described above is provided by way of illustration only and should not be construed as limiting. Various modifications and changes can be made to the subject matter described herein without following the example embodiments and applications illustrated and described, and without departing from the true spirit and scope of the invention encompassed by the present disclosure, which is defined by the set of recitations in the following claims and by structures and functions or steps which are equivalent to these recitations.

What is claimed is:

1. An automated method for dynamically modelling a petroleum reservoir, the method comprising:
running, by a processing circuit, an integrated reservoir model of the petroleum reservoir built from an integrated database of data obtained from measurements of the petroleum reservoir and stored on a non-transitory storage device,
wherein the integrated database of data comprises static data that does not change over time, and dynamic data that changes over time;
wherein the petroleum reservoir has a plurality of petroleum wells represented in the integrated reservoir model,
wherein the integrated database comprises an integration of data obtained from different reservoir disciplines,
wherein the integrated reservoir model is built from the different reservoir disciplines and comprises an integration of a static model built from the static data, and a dynamic model built from the dynamic data, and
wherein the integrated reservoir model is further built through history matching on a respective plurality of measurement data from the plurality of petroleum wells and that is stored in the integrated database, in order to describe an operational behavior of the petroleum reservoir in terms of a set of parameters calibrated by the plurality of measurement data;
obtaining, by the processing circuit, new measurement data from a new petroleum well of the petroleum reservoir and that is not part of the plurality of petroleum wells;
storing, by the processing circuit, the obtained new measurement data in the integrated database;
updating, by the processing circuit, the set of calibrated parameters to reflect the stored new measurement data within a predefined distance of the new petroleum well while not updating the set of calibrated parameters outside the predefined distance of the new petroleum well; and
running, by the processing circuit, the integrated reservoir model with the updated set of calibrated parameters in order to reflect the new petroleum well in the integrated reservoir model.

2. The method of claim 1, wherein the different reservoir disciplines comprise three or more of geology, geophysics, petrophysics, reservoir engineering, and fluid dynamics.

3. The method of claim 1, wherein the measurement data for each petroleum well of the petroleum reservoir comprises a well top, a deviation survey, a porosity log, a permeability log, and an initial water saturation.

4. The method of claim 1, wherein the static model incorporates structural, stratigraphical, and petrophysical features of the petroleum reservoir.

5. The method of claim 1, wherein the static model comprises spatial position information of different formations, faults, folds, and the plurality of petroleum wells in the petroleum reservoir.

6. The method of claim 1, wherein the measurement data comprises pressure-volume-temperature (PVT) data, special core analysis (SCAL) data, oil production data, pressure data, and vertical lift performance (VLP) data.

7. The method of claim 1, further comprising running the integrated reservoir model with the updated set of calibrated parameters in order to identify areas of unswept oil.

8. An automated system for dynamically modelling a petroleum reservoir, the system comprising:
a processing circuit;
a first non-transitory storage device storing an integrated reservoir model of the petroleum reservoir built from an integrated database of data obtained from measurements of the petroleum reservoir;
a second non-transitory storage device storing the integrated database of data; and
a third non-transitory storage device storing instructions thereon that, when executed by the processing circuit, cause the processing circuit to:
run the integrated reservoir model,
wherein the integrated database of data comprises static data that does not change over time, and dynamic data that changes over time;
wherein the petroleum reservoir has a plurality of petroleum wells represented in the integrated reservoir model,
wherein the integrated database comprises an integration of data obtained from different reservoir disciplines,
wherein the integrated reservoir model is built from the different reservoir disciplines and comprises an integration of a static model built from the static data, and a dynamic model built from the dynamic data, and
wherein the integrated reservoir model is further built through history matching on a respective plurality of measurement data from the plurality of petroleum wells and that is stored in the integrated database, in order to describe an operational behavior of the petroleum reservoir in terms of a set of parameters calibrated by the plurality of measurement data;
obtain new measurement data from a new petroleum well of the petroleum reservoir and that is not part of the plurality of petroleum wells;
store the obtained new measurement data in the integrated database;
update the set of calibrated parameters to reflect the stored new measurement data within a predefined distance of the new petroleum well while not updating the set of calibrated parameters outside the predefined distance of the new petroleum well; and
run the integrated reservoir model with the updated set of calibrated parameters in order to reflect the new petroleum well in the integrated reservoir model.

9. The system of claim 8, wherein the different reservoir disciplines comprise three or more of geology, geophysics, petrophysics, reservoir engineering, and fluid dynamics.

10. The system of claim 8, wherein the measurement data for each petroleum well of the petroleum reservoir comprises a well top, a deviation survey, a porosity log, a permeability log, and an initial water saturation.

11. The system of claim 8, wherein the static model incorporates structural, stratigraphical, and petrophysical features of the petroleum reservoir.

12. The system of claim 8, wherein the static model comprises spatial position information of different formations, faults, folds, and the plurality of petroleum wells in the petroleum reservoir.

13. The system of claim 8, wherein the measurement data comprises pressure-volume-temperature (PVT) data, special core analysis (SCAL) data, oil production data, pressure data, and vertical lift performance (VLP) data.

14. The system of claim 8, wherein the instructions, when executed by the processing circuit, further cause the processing circuit to run the integrated reservoir model with the updated set of calibrated parameters in order to identify areas of unswept oil.

15. A non-transitory computer readable medium (CRM) having computer instructions stored therein that, when executed by a processing circuit, cause the processing circuit to carry out an automated process of dynamically modelling a petroleum reservoir, the process comprising:
running an integrated reservoir model of the petroleum reservoir built from an integrated database of data obtained from measurements of the petroleum reservoir and stored on a non-transitory storage device,
wherein the integrated database of data comprises static data that does not change over time, and dynamic data that changes over time;
wherein the petroleum reservoir has a plurality of petroleum wells represented in the integrated reservoir model,
wherein the integrated database comprises an integration of data obtained from different reservoir disciplines,
wherein the integrated reservoir model is built from the different reservoir disciplines and comprises an integration of a static model built from the static data, and a dynamic model built from the dynamic data, and
wherein the integrated reservoir model is further built through history matching on a respective plurality of measurement data from the plurality of petroleum wells and that is stored in the integrated database, in order to describe an operational behavior of the petroleum reservoir in terms of a set of parameters calibrated by the plurality of measurement data;
obtaining new measurement data from a new petroleum well of the petroleum reservoir and that is not part of the plurality of petroleum wells;
storing the obtained new measurement data in the integrated database;
updating the set of calibrated parameters to reflect the stored new measurement data within a predefined distance of the new petroleum well while not updating the set of calibrated parameters outside the predefined distance of the new petroleum well; and
running the integrated reservoir model with the updated set of calibrated parameters in order to reflect the new petroleum well in the integrated reservoir model.

16. The CRM of claim 15, wherein the different reservoir disciplines comprise three or more of geology, geophysics, petrophysics, reservoir engineering, and fluid dynamics.

17. The CRM of claim 15, wherein the measurement data for each petroleum well of the petroleum reservoir comprises a well top, a deviation survey, a porosity log, a permeability log, and an initial water saturation.

18. The CRM of claim 15, wherein the static model incorporates structural, stratigraphical, and petrophysical features of the petroleum reservoir, and the static model comprises spatial position information of different formations, faults, folds, and the plurality of petroleum wells in the petroleum reservoir.

19. The CRM of claim 15, wherein the measurement data comprises pressure-volume-temperature (PVT) data, special core analysis (SCAL) data, oil production data, pressure data, and vertical lift performance (VLP) data.

20. The CRM of claim 15, wherein the process further comprises running the integrated reservoir model with the updated set of calibrated parameters in order to identify areas of unswept oil.
